(19) United States
(12) Patent Application Publication
(10) Pub. No.: US 2014/0262044 A1
(43) Pub. Date: Sep. 18, 2014

(54) MU METAL SHIELD COVER

(71) Applicant: APPLIED MATERIALS, INC., SANTA CLARA, CA (US)

(72) Inventors: IMAD YOUSIF, SAN JOSE, CA (US); SAMER BANNA, SAN JOSE, CA (US); WAHEB BISHARA, MENLO PARK, CA (US); ALVARO GARCIA DE GORORDO, SAN FRANCISCO, CA (US)

(21) Appl. No.: 14/196,360

(22) Filed: Mar. 4, 2014

Related U.S. Application Data
(60) Provisional application No. 61/794,552, filed on Mar. 15, 2013.

(51) Int. Cl. H01J 37/32

(52) U.S. Cl. CPC H01J 37/3266
USPC 156/345.48; 118/723 R; 118/723 I; 156/345.51

(57) ABSTRACT

Embodiments of the present invention generally relate to an apparatus for processing substrates having improved magnetic shielding. One embodiment of the present invention provides a plasma processing chamber having an RF match, a plasma source and a plasma region defined between a chamber ceiling and a substrate support. At least one of the RF match, plasma source and plasma region is shielded from any external magnetic field with a shielding material that has a relative magnetic permeability ranging from about 20,000 to about 200,000. As a result, the inherent process non-uniformities of the hardware may be reduced effectively without the overlaid non-uniformities from external factors such as earth's geomagnetic field.

### CROSS-REFERENCE TO RELATED APPLICATIONS

This application claims benefit of U.S. Provisional Patent Application Ser. No. 61/794,552, filed Mar. 15, 2013, which is herein incorporated by reference.

### BACKGROUND

1. Field

Embodiments of the present invention generally relate to a substrate processing system. More particularly, embodiments of the present invention relate to an apparatus for improving the uniformity of plasma processing techniques used in such substrate processing system.

2. Description of the Related Art

During manufacturing of microelectronic devices, inductively coupled plasma reactors are used in various processes. Conventional inductively coupled plasma reactors generally include a vacuum chamber having a side wall and a ceiling, a workpiece support pedestal within the chamber and generally facing the ceiling, a gas inlet capable of supplying one or more processing gases into the chamber, and one or more coil antennas overlying the ceiling.

For a typical plasma process, a wide range of process conditions is to generate plasma characteristics for a given application. The hardware utilized generally has inherent non-uniformities of varying degrees based on the process conditions. These non-uniformities may cause skews, which sometimes can be compensated by hardware or software adjustment. However, the skews caused by inherent non-uniformities of hardware sometimes overlay with non-uniformities caused by external factors, such as magnetic field of the earth and magnetic field of surrounding processing chambers. The overlaid non-uniformities are difficult to compensate or adjust because the external factors may be random and difficult to predict.

Attempts have been made to reduce or eliminate skews caused by the external factors. These attempts typically involving adding shielding between plasma reactors. However, these extra large parts can be costly and space is not always available between reactors.

Therefore, there is a need for an improved apparatus for reducing skews caused by the external factors.

### SUMMARY

Embodiments of the present invention generally relate to an apparatus for processing substrates having improved magnetic shielding. One embodiment of the present invention provides a plasma processing chamber having an RF match, a plasma source and a plasma region defined between a chamber ceiling and a substrate support. At least one of the RF match, plasma source and plasma region is shielded from any external magnetic field with a shielding material that has a relative magnetic permeability ranging from about 20,000 to about 200,000.

In one embodiment, an apparatus for processing a substrate is disclosed. The apparatus includes a chamber body having a side wall, a bottom, and a ceiling defining an interior processing region. The apparatus also includes a plasma source disposed over the ceiling, an RF match coupled to the plasma source and disposed over the ceiling, and a cover covering sides and a top of the RF match. The cover includes a material having a relative magnetic permeability ranging from about 20,000 to about 200,000. The apparatus further includes a substrate support disposed in the interior processing region of the chamber body facing the ceiling.

In another embodiment, an apparatus for processing a substrate is disclosed. The apparatus includes a chamber body having a side wall, a bottom, and a ceiling defining an interior processing region. The apparatus also includes a plasma source disposed over the ceiling, a first shield circumscribing and aligned with the plasma source, an RF match coupled to the plasma source, and a substrate support disposed in the interior processing region of the chamber body facing the ceiling. The area between the substrate support and the ceiling defines a plasma region. The apparatus further includes a second shield disposed outside the side wall and circumscribing the plasma region.

In another embodiment, an apparatus for etching a substrate is disclosed. The apparatus includes a chamber body having a side wall, a bottom, and a ceiling defining an interior processing region. The apparatus also includes a plasma source disposed over the ceiling, a first magnetic shield circumscribing the plasma source, an RF match coupled to the plasma source, and a cover covering sides and a top of the RF match. The cover includes a material having a relative magnetic permeability ranging from about 20,000 to about 200,000. The apparatus further includes a substrate support disposed in the interior processing region of the chamber body facing the ceiling. The area between the substrate support and the ceiling defines a plasma region. The apparatus further includes a second magnetic shield disposed outside the side wall and circumscribing the plasma region.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically illustrates a sectional view of a plasma processing system according to one embodiment of the invention.

FIG. 2 illustrates magnetic shields for a plasma processing system according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to an apparatus for processing substrates having improved magnetic shielding. More particularly, embodiments of the present invention provide a plasma etch chamber having a magnetic shield disposed around at least one of an RF match, a plasma source and a plasma region defined between a chamber ceiling and a substrate support. The shielding material has a relative magnetic permeability ranging from about 20,000 to about 200,000. By reducing or eliminating the non-uniformities caused by external magnetic field, such as earth's magnetic field, the inherent non-uniformities of the hardware may be reduced effectively.

FIG. 1 illustrates a schematic cross-sectional view of a process chamber 100 according to one embodiment of the invention. The process chamber 100 may be an etch chamber, a plasma enhanced chemical vapor deposition chamber, or a physical vapor deposition chamber. The process chamber 100 generally includes a chamber body 102 having a bottom wall 104, a side wall 103, and a ceiling 108 defining an interior processing region 105. In one embodiment, the ceiling 108 is a dielectric window and is substantially flat. Other embodiments of the process chamber 100 may have other types of ceilings, e.g., a dome-shaped ceiling. A substrate support 126 is disposed in the interior processing region 105 having a substrate receiving surface facing the ceiling 108. The area between the substrate support 126 and the ceiling 108 is defined as a plasma region 107. Typically, the side wall 103 is formed from a metal, such as aluminum, stainless steel, and the like, and is coupled to an electrical ground 106. A slit valve opening 190 is formed through the side wall 103 to allow passage of substrates and substrate transfer mechanism used to place and retrieve substrates from the substrate support 126.

A plasma source 110 is disposed over the ceiling 108. The plasma source 110 may be any plasma source. In one embodiment, the plasma source 110 is an antenna comprising one or more inductive coil elements that may be selectively controlled (two co-axial elements 110a and 110b are shown in FIG. 1). The plasma source 110 is circumscribed by a plasma source side wall 172, and the plasma source side wall 172 supports a plasma source ceiling 174. The plasma source ceiling 174 may be a grounding plate. The plasma source 110 is coupled through an RF match 114 to an RF power source 112. The RF match 114 is coupled to the plasma source 110 through openings in the plasma source ceiling 174. The RF power source 112 is typically capable of producing up to about 3000 Watts (W) at a tunable frequency in a range from about 100 kHz to about 60 MHz. A cover 170 covers the sides and the top of the RF match 114.

A gas panel 120 is coupled to the process chamber 100 to provide process and/or other gases to the interior of the chamber body 102. In the embodiment depicted in FIG. 1, the gas panel 120 is coupled to one or more inlets 116 formed in a channel 118 in the side wall 103 of the chamber body 102. A plasma is formed by applying RF power to the processing gases and is confined in the plasma region 107. It is contemplated that the one or more inlets 116 may be provided in other locations, for example, in the ceiling 108 of the process chamber 100. The process gases are selected to selectively etch a target material disposed on a substrate 122. Examples of common process gases include oxygen containing gases, chlorine containing gases, and fluorine containing gases, among others.

The pressure in the process chamber 100 is controlled using a throttle valve 162 and a vacuum pump 164. The vacuum pump 164 and throttle valve 162 are capable of maintaining chamber pressures in the range of about 0.2 to about 20 mTorr.

The substrate support 126 is used to support a substrate 122. The substrate support 126 is coupled through a matching network 142 to a biasing power source 140. The biasing power source 140 provides biasing power between about 5 to about 500 W at a tunable pulse frequency in the range of about 500 Hz to about 10 kHz. The biasing power source 140 produces pulsed RF power output. Alternatively, the biasing power source 140 may produce pulsed DC power output. It is contemplated that the biasing power source 140 may also provide a constant DC and/or RF power output. The biasing gives the substrate support 126 a positive charge, which attracts the slightly negatively charged plasma, to achieve more anisotropic etch profiles.

In one embodiment, the substrate support 126 includes an electrostatic chuck 160. The electrostatic chuck 160 comprises at least one clamping electrode 132 and is controlled by a chuck power supply 166. In alternative embodiments, the substrate support 126 may comprise substrate retention mechanisms such as a susceptor clamp ring, a vacuum chuck, a mechanical chuck, and the like.

In one embodiment, the electrostatic chuck 160 has a radially outward-extending ledge 168 located below an upper surface 169 of the electrostatic chuck 160, as shown in FIG. 1. The upper surface 169 supports the substrate 122 during processing. A process ring 180 is disposed on the ledge 168 and circumscribes the upper surface 169.

A lift mechanism 138 is used to lower or raise the substrate 122, onto or off of the substrate support 126. Generally, the lift mechanism 138 comprises a plurality of lift pins (one lift pin 130 is shown) that travel through respective guide holes 136.

A backside gas (e.g., helium (He)) from a gas source 156 is provided via a gas conduit 158 to outlets, such as channels 159, formed on the upper surface 169 of the substrate support 126 under the substrate 122.

The controller 146 comprises a central processing unit (CPU) 150, a memory 148, and support circuits 152 for the CPU 150 and facilitates control of the components of the process chamber 100 and, as such, of the etch process, as discussed below in further detail. The controller 146 may be one of any form of general-purpose computer processor that can be used in an industrial setting for controlling various chambers and sub-processors. The memory 148 of the CPU 150 may be one or more of readily available memory such as random access memory (RAM), read only memory (ROM), floppy disk, hard disk, or any other form of digital storage, local or remote. The support circuits 152 are coupled to the CPU 150 for supporting the processor in a conventional manner. These circuits include cache, power supplies, clock circuits, input/output circuitry and subsystems, and the like. The inventive method is generally stored in the memory 148 or other computer-readable medium accessible to the CPU 150 as a software routine. Alternatively, such software routine may also be stored and/or executed by a second CPU (not shown) that is remotely located from the hardware being controlled by the CPU 150.

Historically, an aluminum cover having the same shape and dimensions as the cover 170 is utilized to cover the RF match 114 and other components disposed over the plasma source ceiling 174 for cosmetic and safety purposes. In addition, moving parts may be disposed over the plasma source ceiling 174, thus the aluminum cover shields persons from moving hazards. However, the aluminum cover has never been utilized as a magnetic shield. The magnetic permeability of a metal is understood to refer to the ratio of magnetic flux induced in the metal to the strength of the magnetic field that induces that flux, which is generally refer to as relative magnetic permeability. Accordingly, a metal's high relative magnetic permeability ensures that magnetic flux will be concentrated on the metal, thus making the metal an effective magnetic shield. Aluminum has a relative magnetic permeability of about 1, which is too low to effectively block external magnetic fields, such as earth's magnetic field.

To provide an effective magnetic shield, the cover 170 is made of a material, such as a high-μ (μ is referring to permeability of a material to magnetic fields) material, having a relative magnetic permeability ranging from about 20,000 to about 200,000 and a thickness of about 0.04 inches or thicker. Examples of such material include MUMETAL®, HIPERNOM®, and PERMALLOY®. The material used for the cover 170 may also have a nickel content of greater than 75 percent (%). Thus, in addition to functioning as a cosmetic and safety cover, the cover 170 also functions as a magnetic shield to block external magnetic fields, such as earth's magnetic field and/or magnetic field from adjacent process chambers. Thus, skews in various process conditions caused by external magnetic fields may be minimized. In one embodiment, one of the process conditions is etch rate.

Additional magnetic shields may also be coupled to the process chamber 100 to block external magnetic fields. Typically the side wall 103 of the process chamber 100 and the plasma source side wall 172 are made of aluminum. As described above, aluminum has a low relative magnetic permeability and is not suitable for effectively blocking magnetic fields. The aluminum plasma source side wall may also function as an RF shield. Thus, external magnetic fields, such as earth' magnetic field, may cause skews in various process conditions. By selectively placing magnetic shields on the process chamber 100, external magnetic fields are effectively blocked.

In one embodiment, the cover 170 is coupled to the plasma source side wall 172 and covering the RF match 114. There is about 1 inch clearance between the top of the RF match 114 and the cover 170. The cover 170 may have a plurality of holes disposed on a top surface to allow for forced cooling air to exit. In another embodiment, a magnetic shield 175 may be coupled to the plasma source side wall 172 and circumscribing the plasma source 110. The magnetic shield 175 may be vertically aligned and made of the same material as the cover 170. The magnetic shield 175 may be two semi-circular, vertically aligned sheets that clamp to the outside of the plasma source side wall 172. The magnetic shield 175 may have a thickness of about 0.04 inches or thicker.

In one embodiment, another magnetic shield 182 is coupled to the side wall 103 and circumscribing the plasma region 107. The magnetic shield 182 may be a vertically aligned sheet material circumscribing the plasma region 107 and may be made of the same material as the cover 170. The magnetic shield 182 may have a thickness of about 0.04 inches or thicker. The cover 170 and magnetic shields 175, 182 may be utilized individually or in combination to block external magnetic fields.

FIG. 2 illustrates magnetic shields 200 for a plasma processing system according to one embodiment of the invention. The magnetic shields 200 may be fabricated similar to the cover 170 and magnetic shields 175, 182 described above, for example, the magnetic shields 200 may be made of a high-μ material as described above. The magnetic shields 200 may include a top cover 202, a chamber body shield 204, and a chamber body adapter 206. Unlike the cover 170 illustrated in FIG. 1 that only covers the match 114, the top cover 202 covers both the match 114 and the plasma source 110. In one embodiment, the top cover 202 has a thickness of about 0.06 inches. The top cover 202 may also have a plurality of holes disposed on a top surface to allow for forced cooling air to exit.

The chamber body shield 204 may be circumscribing the side wall 103, except for the side where the slit valve opening 190 is located. In one embodiment, the chamber body shield 204 has the same thickness as the top cover 202.

In order to shield the side of the chamber where the slit valve opening is located while not blocking the transferring of the substrates, the chamber body adaptor 206 is utilized. The chamber body adaptor 206 has an opening 208 that aligns with the slit valve opening 108 to allow substrates to be robotically transferred into and out of the processing chamber. The chamber body adaptor 206 may be thicker than the top cover 202 and the chamber body shield 204. In one embodiment, the chamber body adaptor 206 is about 0.5 inches thick.

In summary, by replacing the aluminum cover covering the RF match with a cover made of a material having a high relative magnetic permeability, skews caused by external magnetic fields such as earth's magnetic field is minimized. Additional magnetic shields may be covering the plasma source and the plasma region to enhance magnetic shielding.

While the foregoing is directed to embodiments of the present invention, other and further embodiments of the invention may be devised without departing from the basic scope thereof, and the scope thereof is determined by the claims that follow.

What is claimed is:

1. An apparatus for processing a substrate, comprising:
a chamber body having a side wall, a bottom, and a ceiling defining an interior processing region;
a plasma source disposed over the ceiling;
an RF match coupled to the plasma source and disposed over the ceiling;
a cover covering sides and a top of the RF match and the plasma source, wherein the cover comprises a material having a relative magnetic permeability ranging from about 20,000 to about 200,000; and
a substrate support disposed in the interior processing region of the chamber body facing the ceiling.

2. The apparatus of claim 1, wherein the plasma source comprises at least one inductive coil.

3. The apparatus of claim 2, further comprising a shield circumscribing the side wall of the chamber body, wherein the shield has a chamber body adaptor.

4. The apparatus of claim 3, wherein the shield comprises a sheet material having a relative magnetic permeability ranging from about 20,000 to about 200,000.

5. The apparatus of claim 4, wherein the chamber body adaptor has an opening aligned with a slit valve opening in the side wall.

6. The apparatus of claim 1, wherein the ceiling is a dielectric window.

7. An apparatus for processing a substrate, comprising:
a chamber body having a side wall, a bottom, and a ceiling defining an interior processing region;
a shield circumscribing the side wall of the chamber body, wherein the first shield has a chamber body adaptor;
a plasma source disposed over the ceiling;
an RF match coupled to the plasma source; and
a cover covering sides and a top of the RF match and the plasma source.

8. The apparatus of claim 7, wherein the ceiling is a dielectric window.

9. The apparatus of claim 8, wherein the shield comprises a sheet material having a relative magnetic permeability ranging from about 20,000 to about 200,000.

10. The apparatus of claim 9, wherein the chamber body adaptor has an opening aligned with a slit valve opening in the side wall.

11. The apparatus of claim 10, wherein the plasma source comprises at least one inductive coil.
